(19) United States
(12) Patent Application Publication
(10) Pub. No.: US 2017/0136505 A1
(43) Pub. Date: May 18, 2017

(54) TEMPLATE CLEANING METHOD, TEMPLATE CLEANING APPARATUS, AND IMPRINT METHOD

(71) Applicant: Kabushiki Kaisha Toshiba, Minato-ku (JP)

(72) Inventor: Shinji YAMAGUCHI, Yokkaichi (JP)

(73) Assignee: Kabushiki Kaisha Toshiba, Minato-ku (JP)

(21) Appl. No.: 15/014,169

(22) Filed: Feb. 3, 2016

(30) Foreign Application Priority Data
Nov. 13, 2015 (JP) 2015-223021

(51) Int. Cl. B08B 7/00; B08B 3/08; B08B 3/12; B29C 59/00; G03F 7/00; B29C 59/02; B29C 35/08; B08B 3/10; B08B 3/02

(52) U.S. Cl. CPC B08B 7/0021; B08B 3/102; B08B 3/10; B08B 3/08; B08B 3/12; B08B 3/02; G03F 7/0002; B29C 59/02; B29C 35/0805; B29C 59/002; B29C 2035/0827

(57) ABSTRACT

According to an embodiment, at first, a template is put into a cleaning bath containing a cleaning liquid inside a first process chamber. Then, an inactive gas is supplied into the first process chamber and the cleaning liquid is heated, so as to set temperature and pressure conditions that turn the cleaning liquid into a supercritical fluid state or subcritical fluid state. Then, the template is immersed in the cleaning liquid in the supercritical fluid state or subcritical fluid state for a predetermined time period.

### CROSS-REFERENCE TO RELATED APPLICATIONS

This application is based upon and claims the benefit of priority from Japanese Patent Application No. 2015-223021, filed on Nov. 13, 2015; the entire contents of which are incorporated herein by reference.

### FIELD

Embodiments described herein relate generally to a template cleaning method, a template cleaning apparatus, and an imprint method.

### BACKGROUND

According to conventional photolithography techniques, a mask and a wafer are set not in contact with each other, and a pellicle is laminated on the mask to avoid foreign matters. Accordingly, deposition of foreign matters on the mask does not pose serious problems. However, in the case of nano-imprint lithography techniques, deposition of foreign matters on a template is thought to be one of the significant risks. This occurs because the template and a wafer are set in contact with each other, and/or because a nano-imprint process during a mass production period brings about a state where a resist on a wafer partly adheres onto the template and/or a state where foreign matters are dropped onto the template from the outside. As a result, in manufacturing semiconductor devices, the yield ratio is lowered and the manufacturing cost is increased.

In light of this, conventionally, a resist deposited on the template is removed by cleaning using an acid, alkali, or resist stripping technique. However, an organic matter (C) contained in the resist deposited on the template may chemically react with silicon (Si) used as a constitution material of the template and thereby form Si—C bonds. The Si—C bonds can be hardly cut by the cleaning described above.

### BRIEF DESCRIPTION OF THE DRAWINGS

FIGS. 1A to 1E are sectional views schematically showing the sequence of an imprint method according to a comparative example;

FIGS. 2A and 2B are sectional views schematically showing a state where a resist adheres onto a template during an imprint process;

FIG. 3 is a view showing an example of a template cleaning apparatus according to a comparative example;

FIG. 4 is a top view schematically showing a structural example of a template cleaning system according to a first embodiment;

FIG. 5 is a sectional view showing a structural example of a template cleaning apparatus used as part of the template cleaning system;

FIG. 6 is a sectional view showing a structural example of a post-processing apparatus used as part of the template cleaning system;

FIG. 7 is a view showing an example of information for determining cleaning conditions;

FIGS. 8A to 8K are top views showing an example of the sequence of a cleaning method performed in the template cleaning system according to the first embodiment;

FIGS. 9A to 9G are sectional views showing the example of the sequence of a cleaning method performed in the template cleaning system according to the first embodiment;

FIG. 10 is a view showing examples of a template defect map;

FIG. 11 is a view schematically showing a general structure of an imprint manufacturing system that includes a template cleaning function according to a second embodiment; and

FIG. 12 is a flow chart showing an example of the sequence of an imprint method according to the second embodiment.

### DETAILED DESCRIPTION

In general, according to one embodiment, at first, a template is put into a cleaning bath containing a cleaning liquid inside a first process chamber. Then, an inactive gas is supplied into the first process chamber and the cleaning liquid is heated, so as to set temperature and pressure conditions that turn the cleaning liquid into a supercritical fluid state or subcritical fluid state. Then, the template is immersed in the cleaning liquid in the supercritical fluid state or subcritical fluid state for a predetermined time period.

Exemplary embodiments of a template cleaning method, a template cleaning apparatus, and an imprint method will be explained below in detail with reference to the accompanying drawings. The present invention is not limited to the following embodiments. In the following description, problems caused by a template cleaning method according to a comparative example will be first explained, and the embodiments will be then explained.

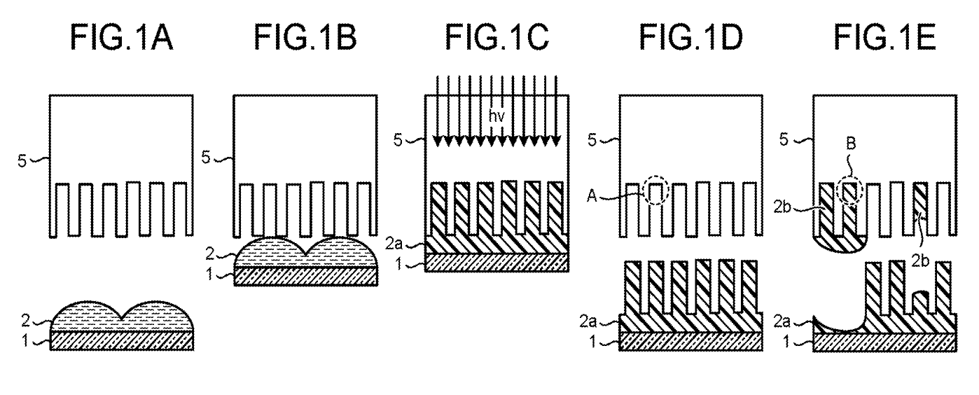

FIGS. 1A to 1E are sectional views schematically showing the sequence of an imprint method according to a comparative example. At first, as shown in FIG. 1A, a resist 2 is dropped onto a wafer 1, and positioning is performed between the wafer 1 and a template 5 including predetermined rugged patterns. Then, as shown in FIG. 1B, the wafer 1 and the template 5 are moved relative to each other to bring the template 5 into contact with the resist 2, and then made to wait for a predetermined time period in this state. Consequently, as shown in FIG. 1C, the recessed patterns of the template 5 are filled with the resist 2. Thereafter, the resist 2 is irradiated with ultraviolet rays, and thereby a cured resist 2a is obtained. Then, the template 5 is separated from the wafer 1. In general, as shown in FIG. 1D, the cured resist 2a is formed with rugged patterns reversed from the rugged patterns formed on the template 5. However, as shown in FIG. 1E, there may be a case that part of the cured resist 2a adheres onto the template 5. This part of the cured resist deposited on the template 5 will be referred to as a fixed resist 2b, hereinafter.

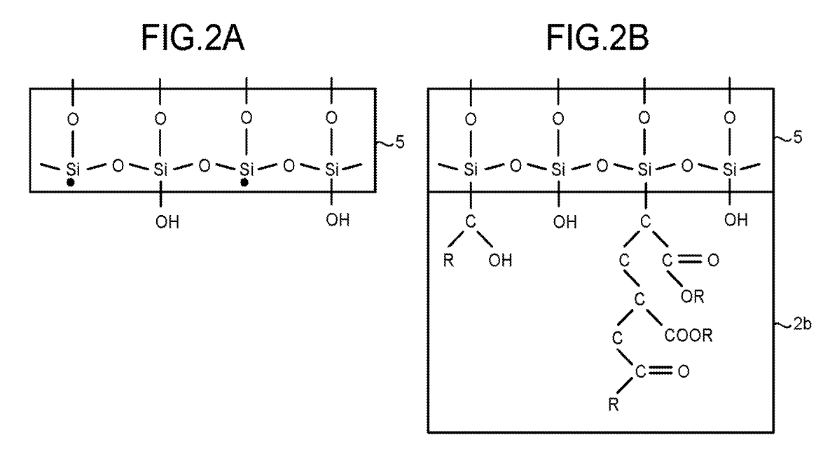

FIGS. 2A and 2B are sectional views schematically showing a state where the resist adheres onto the template during the imprint process. FIG. 2A is a view schematically showing a portion A of FIG. 1D in an enlarged state, and FIG. 2B is a view schematically showing a portion B of FIG. 1E in an enlarged state. As shown in FIG. 2A, the template 5 is made of quartz (SiO₂). Accordingly, the inside of the template 5 is structured such that one silicon (Si) atom is bonded with four oxygen (O) atoms. Further, Si at the outermost surface is in a state where its one atom is bonded with three O atoms and has one bonding hand being free. In some of the atoms of Si at the outermost surface, a bonding hand is bonded with O of a hydroxyl group (OH), for example.

In the imprint method, the template 5 is set in contact with the resist 2, then the resist 2 is cured, and thereby patterns are formed. In this case, as shown in FIG. 2B, carbon (C) of the organic matter contained in the fixed resist 2b deposited on the template 5 chemically reacts with Si constituting the template 5, and thereby forms Si—C bonds. The Si—C bonds have a high binding energy.

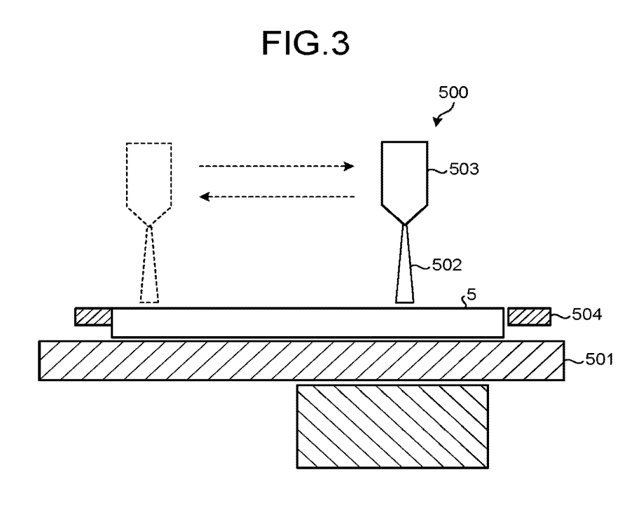

FIG. 3 is a view showing an example of a template cleaning apparatus according to a comparative example. The cleaning apparatus 500 includes a stage 501 for holding a template 5, and a nozzle 503 for delivering a cleaning liquid 502. The stage 501 is configured to rotate the template 5 in a template placement plane. Further, the stage 501 includes a guide 504 for fixing the position of the template 5. The nozzle 503 is configured to be moved by a moving mechanism (not shown) so that it can deliver the cleaning liquid 502 onto the entire surface of the template 5. As the cleaning liquid 502, a solution of an acid or alkali may be used.

The template 5 is placed on the stage 501 of this cleaning apparatus 500, and the stage 501 is rotated. Then, the cleaning liquid 502 is delivered from the nozzle 503 onto the upper surface of the template 5 being rotated, and thereby cleaning is performed to the upper surface of the template 5.

However, even though the cleaning is performed by use of acid or alkali as described above or the cleaning is performed by use of a resist stripping technique, Si—C bonds can be hardly cut. Thus, when the cleaning is performed to the template 5 including the fixed resist 2b deposited thereon as shown in FIG. 1E, the fixed resist 2b cannot be removed from the template 5.

Accordingly, in the embodiment described below, an explanation will be given of a template cleaning apparatus and a template cleaning method, which can remove the fixed resist 2b deposited on the template 5 and stuck by Si—C bonds as shown in FIG. 1E.

### First Embodiment

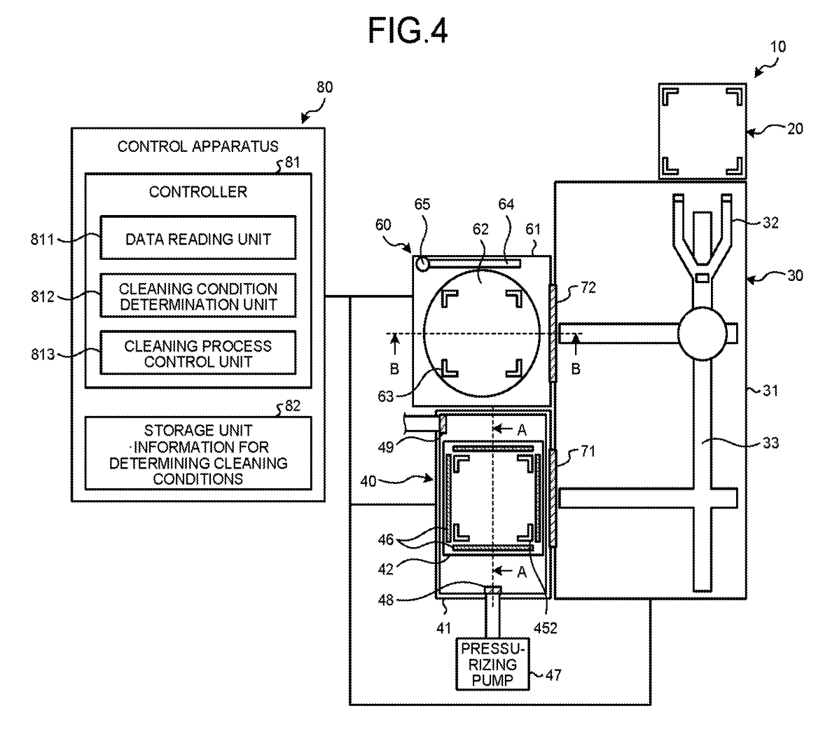

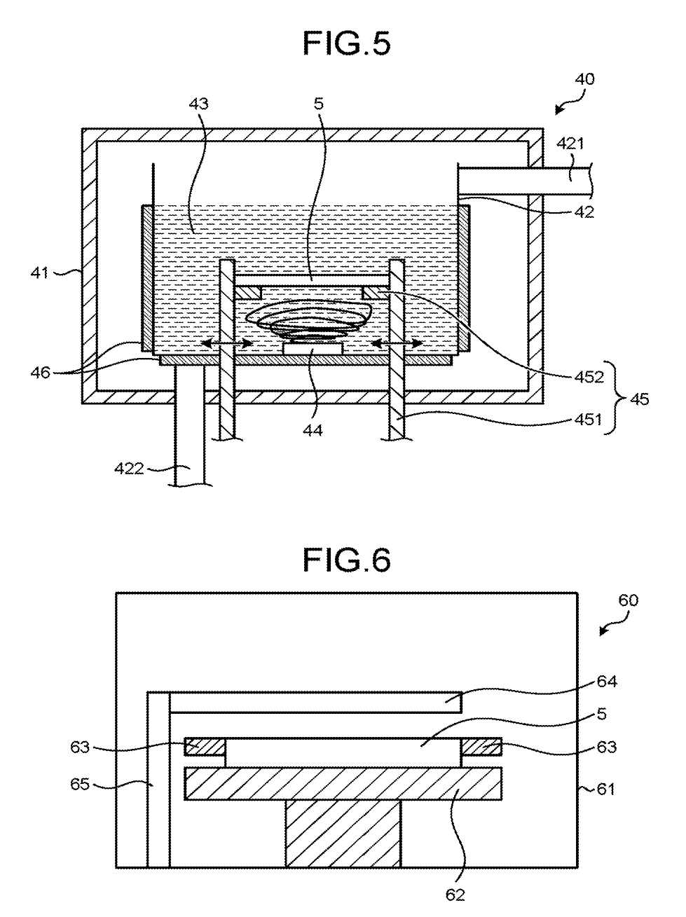

FIG. 4 is a top view schematically showing a structural example of a template cleaning system according to a first embodiment. FIG. 5 is a sectional view showing a structural example of a template cleaning apparatus used as part of the template cleaning system, which is a sectional view taken along a line A-A of FIG. 4. FIG. 6 is a sectional view showing a structural example of a post-processing apparatus used as part of the template cleaning system, which is a sectional view taken along a line B-B of FIG. 4.

The template cleaning system 10 includes a load port 20, a conveying apparatus 30, a template cleaning apparatus 40, a post-processing apparatus 60, and a control apparatus 80. The load port 20 is configured to place a template 5 thereon, which is treated as a processing object in the template cleaning system 10. The load port 20 serves as a doorway through which the template 5 can be loaded into the template cleaning system 10 or unloaded from the template cleaning system 10.

The conveying apparatus 30 is configured to transfer the template 5 between the load port 20, the template cleaning apparatus 40, and the post-processing apparatus 60. The conveying apparatus 30 includes a carrier member 32 and a guide 33, disposed inside a chamber 31. The carrier member 32 is a member that can travel on the guide 33 while holding the template 5. For example, the carrier member 32 is formed of a robot arm or the like. The guide 33 is disposed along the traveling route of the carrier member 32 to define the traveling range of the carrier member 32.

The template cleaning apparatus 40 includes a cleaning mechanism for removing the fixed resist and particles deposited on the template 5. The template cleaning apparatus 40 includes a process chamber 41 having an airtight structure that can withstand a pressure of 100 MPa. Further, the process chamber 41 has been treated with a heat insulating improvement.

Inside the process chamber 41, there is disposed a cleaning bath 42 that can withstand a temperature of up to 1,000° C. The cleaning bath 42 includes a cleaning liquid charge port 421 and a cleaning liquid discharge port 422. A cleaning liquid 43 is supplied into the cleaning bath 42 through the cleaning liquid charge port 421. Further, the cleaning liquid 43 is drained through the cleaning liquid discharge port 422. The cleaning liquid discharge port 422 is equipped with a valve (not shown). During a cleaning process, the valve is in a closed state. As the cleaning liquid, there may be used pure water, an organic solvent, such as isopropyl alcohol, an acid-based solvent, such as sulfuric acid aqueous solution, or an alkali-based solvent, such as ammonia water.

Inside the cleaning bath 42, an agitator 44 and a template holding member 45 are disposed. The agitator 44 is disposed on the bottom of the cleaning bath 42 to agitate the cleaning liquid 43 inside the cleaning bath 42. As the agitator 44, for example, there may be used a magnetic stirrer that employs a rotation magnet to rotate a stirring element formed of a bar magnet sealed with Teflon (R), or an ultrasonic generation device. The agitator 44 is intended to generate a flow of the cleaning liquid 43 to efficiently remove the fixed resist, but the agitator 44 may be not disposed.

The template holding member 45 includes four rods 451 that penetrate the bottom of the cleaning bath 42 and the bottom of the process chamber 41, and support portions 452 respectively attached to the rods 451 to support the template 5. The rods 451 are connected to a drive unit (not shown) outside the process chamber 41. The rods 451 are moved by the drive unit in the vertical direction in FIG. 5, such that the support portions 452 are set to a position higher than the upper side of the cleaning bath 42, or the support portions 452 are set to a predetermined position inside the cleaning bath 42. Here, the portions where the rods 451 penetrate the bottom of the cleaning bath 42 have been processed to prevent leakage of the cleaning liquid 43, and the portions where the rods 451 penetrate the bottom of the process chamber 41 have been processed to prevent leakage of an inactive gas. Further, the rods 451 are connected to a rocking mechanism (not shown) for rocking the rods 451 in a direction along the bottom of the cleaning bath 42. The support portions 452 are sized to support portions of the template 5 near its four corners.

The cleaning bath 42 is equipped with heaters 46 for heating the cleaning liquid 43, on the lateral sides and the bottom. Further, the cleaning bath 42 has been treated with a heat insulating improvement so that the heated cleaning liquid 43 cannot be easily cooled.

The template cleaning apparatus 40 includes a pressurizing pump 47, a pressure increasing valve 48, and a pressure reducing valve 49. The pressurizing pump 47 is a pump that supplies an inactive gas into the process chamber 41. As the inactive gas, nitrogen (N₂), helium (He), argon (Ar), or the like may be used. The pressure increasing valve 48 is a valve disposed between the process chamber 41 and the pressurizing pump 47, which is set open when the pressure inside the process chamber 41 is being increased, and is set closed when the pressure reaches a predetermined pressure. The pressure reducing valve 49 is a valve disposed between the process chamber 41 and the external environment, which is set open to reduce the pressure inside the process chamber 41 in a high pressure state, and is set closed when the pressure reaches the atmospheric pressure.

The post-processing apparatus 60 includes a mechanism for performing a rinse treatment to the template 5 processed by the template cleaning apparatus 40. The post-processing apparatus 60 includes a stage 62 for holding the template 5, and a nozzle 64 for delivering pure water, disposed inside a post-processing chamber 61. The stage 62 is configured to rotate the template 5 in a template placement plane. The stage 62 is connected to a drive mechanism (not shown) for rotating the stage 62. Further, the stage 62 includes a guide 63 for fixing the position of the template 5. The nozzle 64 has a slender cylindrical shape, and its base end is fixed to a nozzle fixing member 65 having a bar shape. The nozzle fixing member 65 is configured to rotate about its extending direction as an axis. Accordingly, the nozzle 64 can be moved across part of the stage 62 by rotation of the nozzle fixing member 65. Thus, when pure water is delivered from the nozzle 64 positioned above the stage 62 while the stage 62 is being rotated, pure water can be supplied onto the entire upper surface of the template 5 on the stage 62. As this pure water, pure water at room temperature and pure water at a temperature higher than the room temperature and lower than 100° C. may be used.

Gate valves 71 and 72 are respectively disposed between the template cleaning apparatus 40 and the conveying apparatus 30, and between the post-processing apparatus 60 and the conveying apparatus 30.

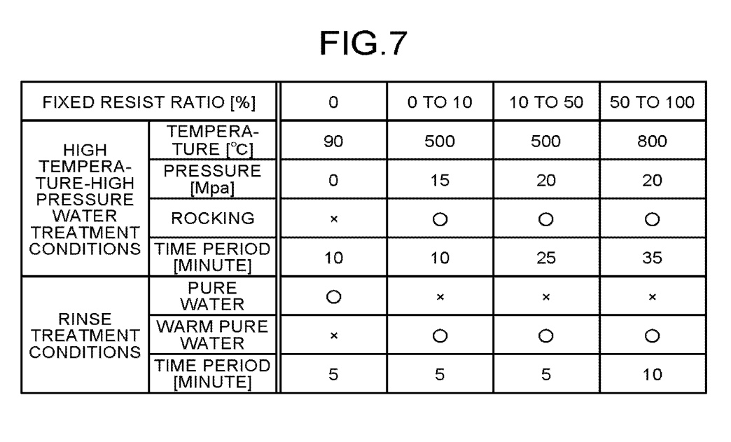

The control apparatus 80 is configured to control the cleaning process performed to the template 5 in the template cleaning system 10. The control apparatus 80 includes a controller 81 and a storage unit 82. The storage unit 82 stores information for determining cleaning conditions. The information for determining cleaning conditions has been prepared such that cleaning conditions are set in correlation to contamination degrees of the template 5 placed on the load port 20. FIG. 7 is a view showing an example of the information for determining cleaning conditions. The information for determining cleaning conditions includes fixed resist ratios on the template 5 and cleaning conditions correlated to the fixed resist ratios. As a fixed resist ratio on the template 5, for example, a ratio of the fixed resist occupying the surface area of the template 5 may be used. The cleaning conditions include conditions for a high temperature-high pressure water treatment performed in the template cleaning apparatus 40, and further include conditions for a rinse treatment performed in the post-processing apparatus 60. The high temperature-high pressure water treatment conditions include a temperature (° C.), a pressure (MPa), the presence or absence of rocking, and a time period (minute), for example. The rinse treatment conditions include the use of pure water/warm pure water and a time period (minute), for example.

In the example shown in FIG. 7, the fixed resist ratio is categorized into four cases, which are formed of a ratio of 0%, a ratio of larger than 0% and not larger than 10%, a ratio of larger than 10% and not larger than 50%, and a ratio of larger than 50% and not larger than 100%. When the fixed resist ratio is 0%, this is a case that the fixed resist is not deposited on the template 5, but, for example, particles have been dropped from the external environment onto the template 5. In this case, the high temperature-high pressure water treatment, i.e., a cleaning process, is performed by immersing the template 5 in the cleaning liquid set to a temperature of 90° C., for 10 minutes, without applying a pressure and without rocking the template 5. When only particles are deposited without deposition of the fixed-resist, the particles can be removed without setting the cleaning liquid to a high temperature-high pressure as describe above, and so the conditions are adopted as describe above. Further, the rinse treatment is performed by spraying room temperature pure water for 5 minutes, for example. The pure water is set to the room temperature, because the template 5 may be thermally affected if the pure water is used at a higher temperature.

When the fixed resist ratio is larger than 0% and not larger than 10%, the high temperature-high pressure water treatment is performed by immersing the template 5 in the cleaning liquid set to a temperature of 500° C. and a pressure of 15 MPa, for 10 minutes, while rocking the template 5. Further, the rinse treatment is performed by spraying warm pure water for 5 minutes. The warm pure water is used, because the cleaning subsequent to the high temperature-high pressure water treatment can provide an improved cleaning effect by use of the warm pure water rather than room temperature pure water.

When the fixed resist ratio is larger than 10% and not larger than 50%, the high temperature-high pressure water treatment is performed by immersing the template 5 in the cleaning liquid set to a temperature of 500° C. and a pressure of 20 MPa, for 25 minutes, while rocking the template 5. Further, the rinse treatment is performed by spraying warm pure water for 5 minutes.

When the fixed resist ratio is larger than 50% and not larger than 100%, the high temperature-high pressure water treatment is performed by immersing the template 5 in the cleaning liquid set to a temperature of 800° C. and a pressure of 20 MPa, for 35 minutes, while rocking the template 5. Further, the rinse treatment is performed by spraying warm pure water for 10 minutes.

In general, along with an increase in the fixed resist ratio, the high temperature-high pressure water treatment conditions are set to include a higher temperature, a higher pressure, and a longer treatment time period. Further, in general, along with an increase in the fixed resist ratio, the rinse treatment conditions using warm pure water are set to include a longer treatment time period.

Here, the information for determining cleaning conditions shown in FIG. 7 is a mere example. For example, FIG. 7 shows four groups of cleaning conditions, but the number of groups of cleaning conditions is arbitrary. Further, in each of the condition groups, the temperature, the pressure, the presence or absence of rocking, the time period of the high temperature-high pressure water treatment, the selection of pure water/warm pure water, and the time period of the rinse treatment may be set to different conditions to remove the fixed resist or particles, within ranges that do not apply excessive loads to the template 5.

The controller 81 includes a data reading unit 811, a cleaning condition determination unit 812, and a cleaning process control unit 813. The controller 81 is constituted by one or a plurality of CPUs (Central Processing Unit) and a peripheral circuit.

The data reading unit 811 is configured to read an examination result of the template 5 treated as a cleaning object. The examination result may be exemplified by image data or the like obtained by imaging the template 5, for example.

The cleaning condition determination unit 812 is configured to calculate a fixed resist ratio from an examination result of the template 5, and to determine cleaning conditions, based on the fixed resist ratio thus calculated, with reference to the information for determining cleaning conditions. For example, the cleaning condition determination unit 812 calculates a ratio of the fixed resist and a ratio of the particles, which occupy the surface area of the template 5, and thereby calculates the fixed resist ratio on the template 5. Then, it obtains cleaning conditions to correspond to the fixed resist ratio, with reference to the information for determining cleaning conditions.

The cleaning process control unit 813 is configured to control the template cleaning system 10 to perform a cleaning process to the template 5 placed on the load port 20, based on the cleaning conditions thus determined. For example, it uses the carrier member 32 of the conveying apparatus 30 to move the template 5 into the template cleaning apparatus 40 or post-processing apparatus 60, and controls the operations of the respective components in the template cleaning apparatus 40 or post-processing apparatus 60.

According to the template cleaning system 10 having the structure described above, the cleaning liquid 43 is set to a high temperature and a high pressure inside the process chamber 41 of the template cleaning apparatus 40 so that the cleaning liquid 43 can be turned into a supercritical fluid or subcritical fluid. The supercritical fluid and subcritical fluid are very high in decomposition activity, and can immediately decompose almost all organic matters. Accordingly, the fixed resist and particles formed of organic matters, which are deposited on the template 5 placed inside the cleaning bath 42, can be removed.

In this respect, the binding energy of an Si—C bond is lower than the binding energy of an Si—O bond. Accordingly, the high temperature-high pressure water treatment conditions are set such that the supercritical fluid or subcritical fluid has an energy of not lower than the binding energy of an Si—C bond but lower than the binding energy of an Si—O bond. For example, in the case that the cleaning liquid 43 is made of pure water, the cleaning liquid 43 can be generated to cut only Si—C bonds, by use of a temperature range of 100° C. or more and 1,000° C. or less, and a pressure range of 10 MPa or more and 100 MPa or less.

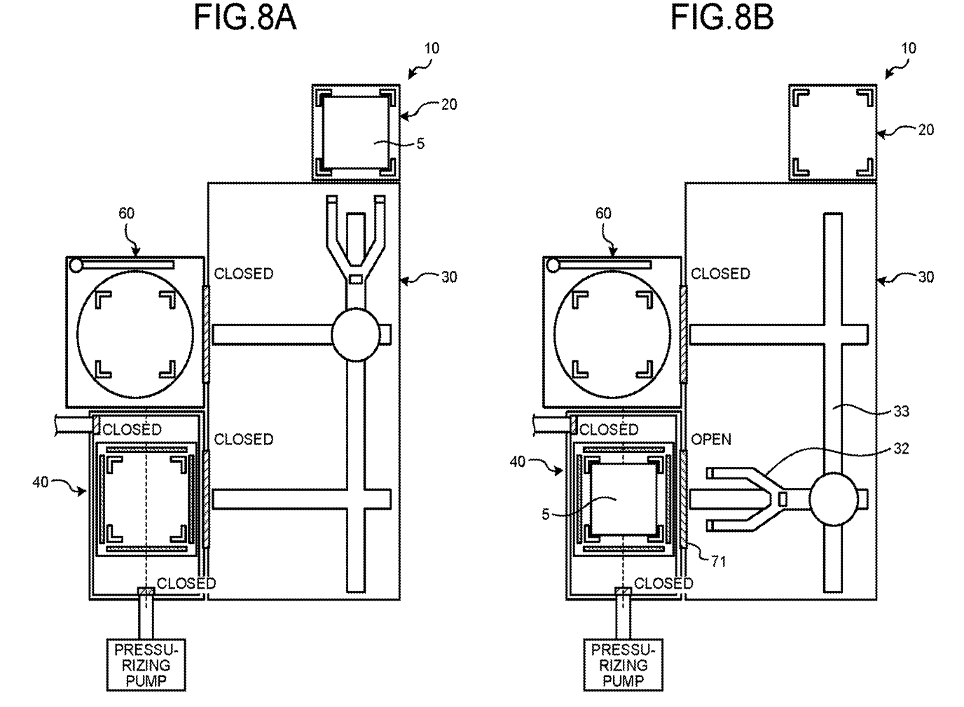

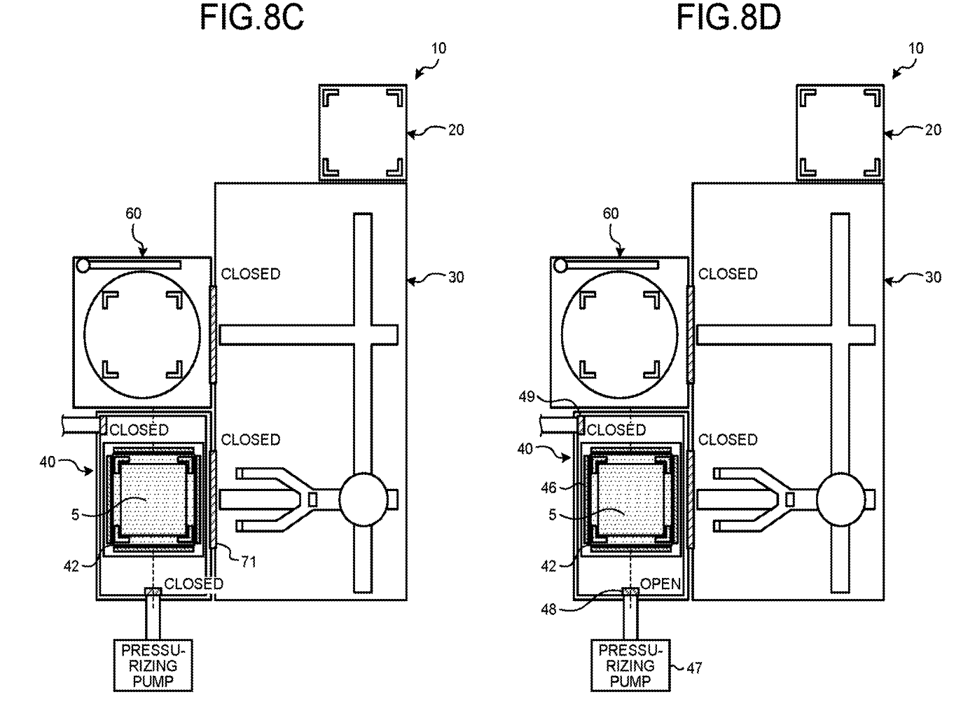

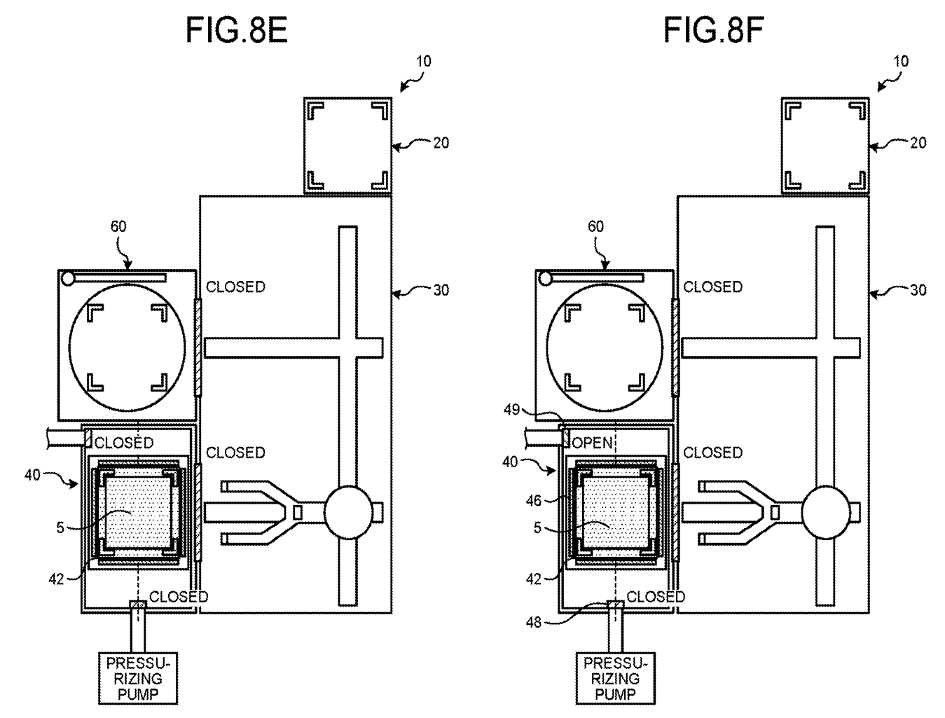

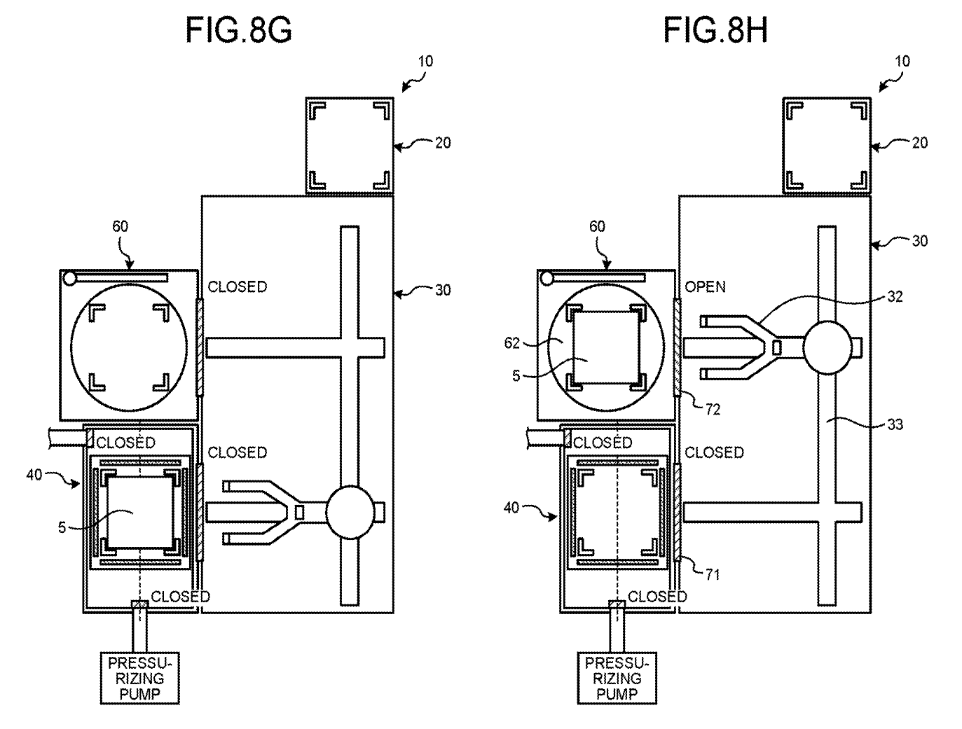

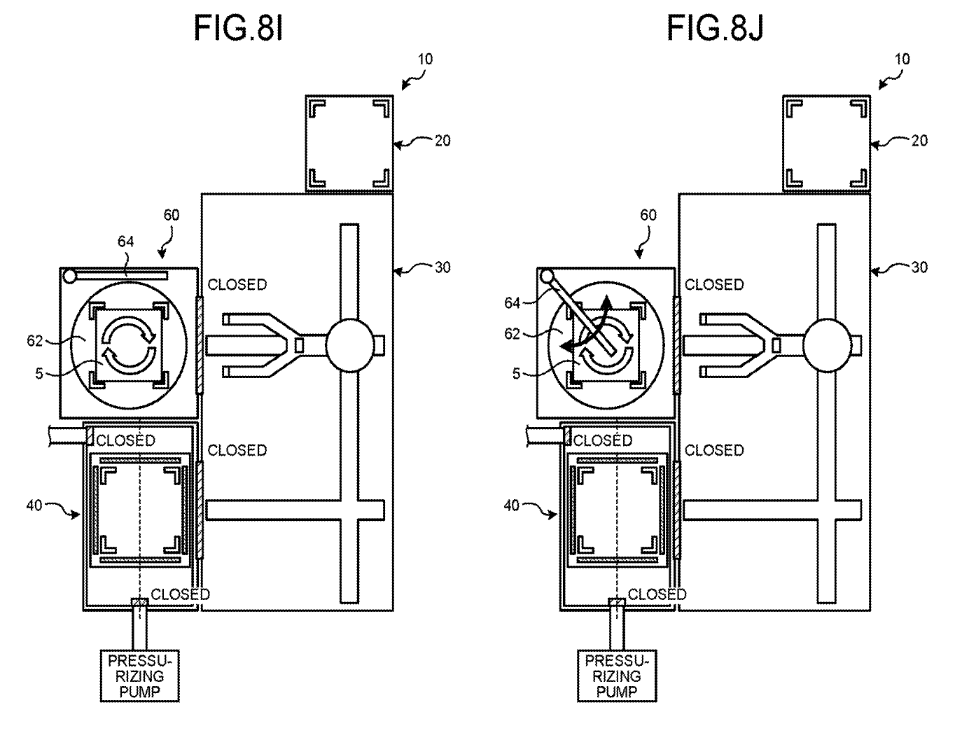

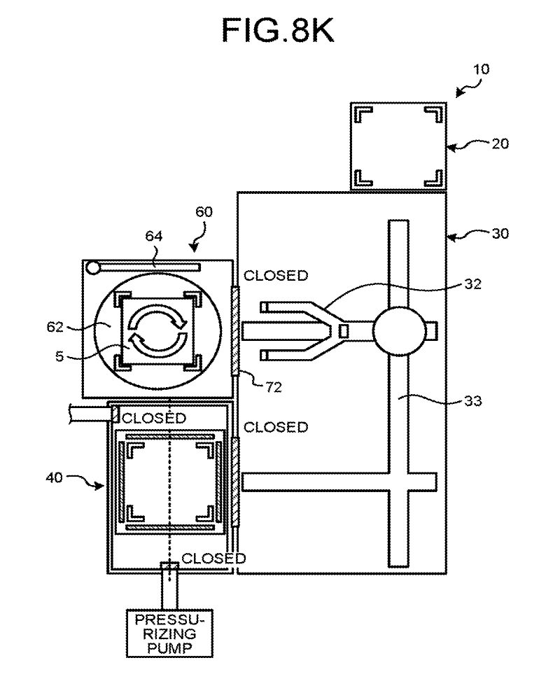

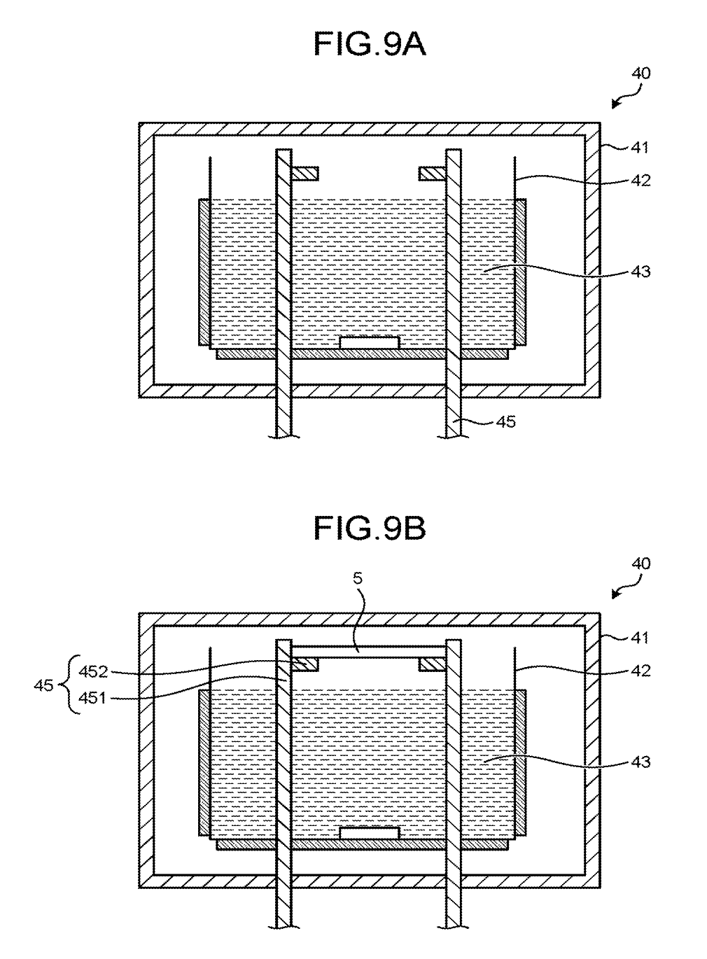

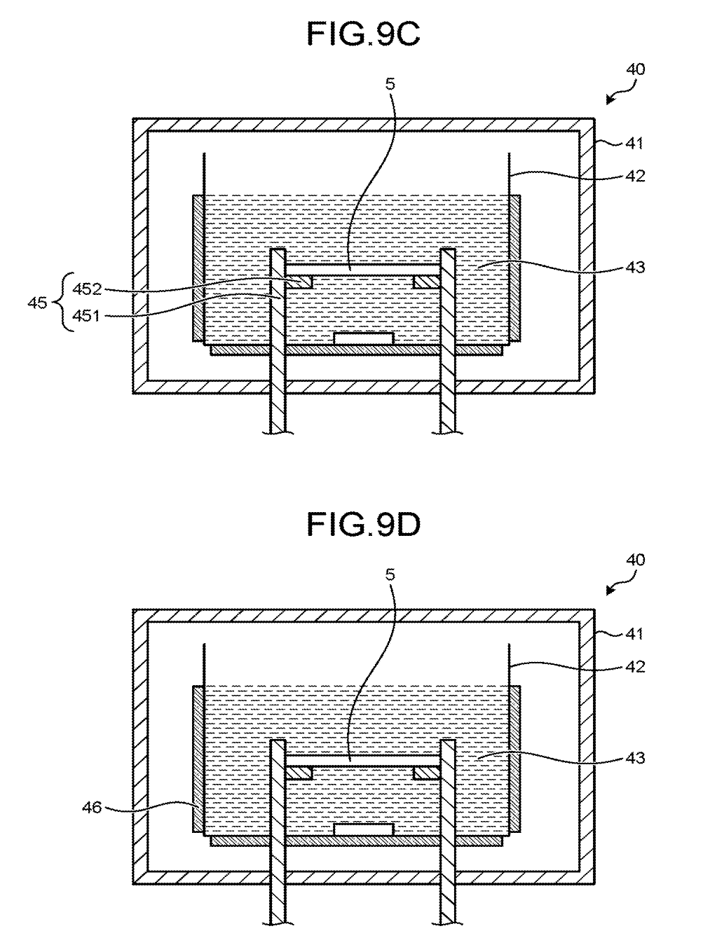

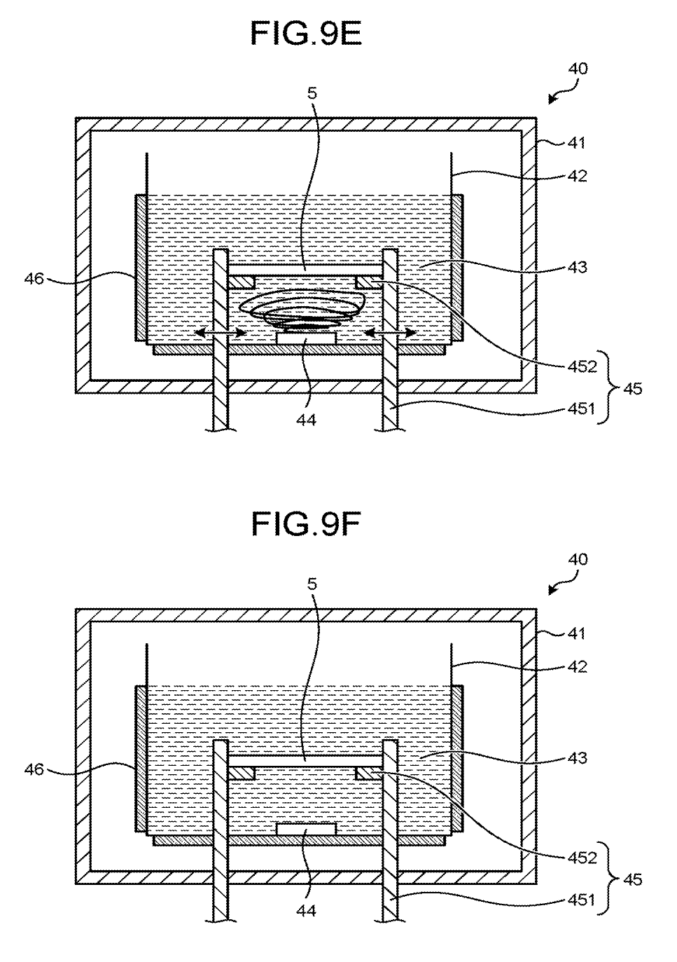

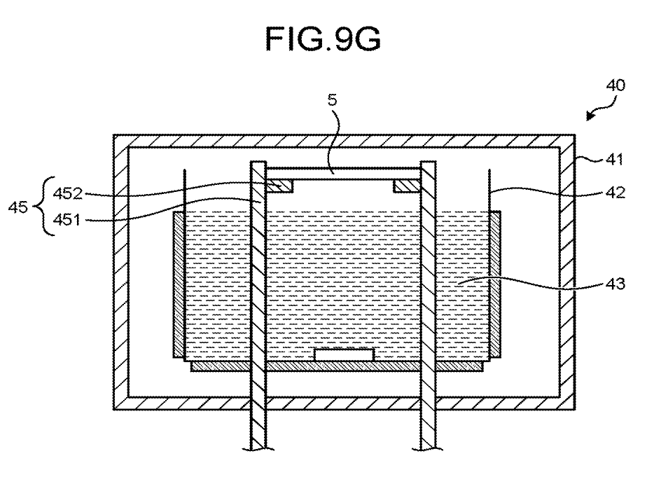

Next, an explanation will be given of a template cleaning method performed in the template cleaning system 10 having the structure described above. FIGS. 8A to 8K are top views showing an example of the sequence of a cleaning method performed in the template cleaning system according to the first embodiment. FIGS. 9A to 9G are sectional views showing the example of the sequence of a cleaning method performed in the template cleaning system according to the first embodiment.

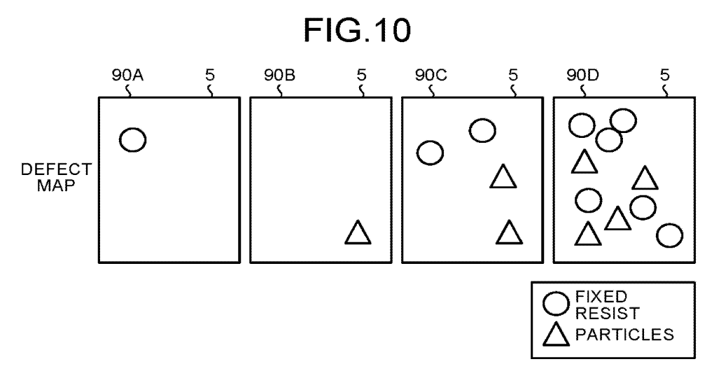

At first, the template 5 is examined. For example, the face of the template 5 formed with rugged patterns is imaged by an imaging apparatus. As the imaging apparatus, an optical microscope or scanning electron microscope may be used. The data reading unit 811 of the control apparatus 80 reads the imaged data as a defect map, and the cleaning condition determination unit 812 determines cleaning conditions. The defect map is an example of information about the pattern formation face. FIG. 10 is a view showing examples of the template defect map. Here, in FIG. 10, a symbol “o” (open circle) indicates the fixed resist, and a symbol “a” (open triangle) indicates the particles.

A defect map 90A shows a state where the fixed resist is deposited at one place and the particles are not deposited, on the template 5. A defect map 90B shows a state where the particles are deposited at one place and the fixed resist is not deposited, on the template 5. A defect map 90C shows a state where the fixed resist and the particles are deposited such that a ratio of the fixed resist and a ratio of the particles are respectively higher than those of the defect maps 90A and 90B. A defect map 90D shows a state where the fixed resist and the particles are deposited such that a ratio of the fixed resist and a ratio of the particles are respectively higher than those of the defect map 90C.

The cleaning condition determination unit 812 calculates, for example, a fixed resist ratio from the defect map thus read, and obtains cleaning conditions to correspond to the fixed resist ratio thus calculated, with reference to the information for determining cleaning conditions.

For example, it is assumed that the defect map 90A is in a state where the fixed resist ratio is larger than 0% and not larger than 10%. In this case, the cleaning condition determination unit 812 selects cleaning conditions for a fixed resist ratio of 0 to 10% in the information for determining cleaning conditions shown in FIG. 7.

On the other hand, if the defect map 90B is obtained, it is assumed that the fixed resist ratio is 0%. In this case, the cleaning condition determination unit 812 selects cleaning conditions for a fixed resist ratio of 0% in the information for determining cleaning conditions shown in FIG. 7.

Further, it is assumed that the defect map 90C is in a state where the fixed resist ratio is larger than 10% and not larger than 50%. In this case, the cleaning condition determination unit 812 selects cleaning conditions for a fixed resist ratio of 10 to 50% in the information for determining cleaning conditions shown in FIG. 7.

Further, it is assumed that the defect map 90D is in a state where the fixed resist ratio is larger than 50% and not larger than 100%. In this case, the cleaning condition determination unit 812 selects cleaning conditions for a fixed resist ratio of 50 to 100% in the information for determining cleaning conditions shown in FIG. 7.

In the following explanation, it is assumed that the defect map 90C is obtained. The cleaning condition determination unit 812 performs cleaning in the template cleaning system 10, based on the cleaning conditions for the fixed resist ratio of 10 to 50%.

Then, as shown in FIGS. 8A and 9A, the template 5 is placed on the load port 20. Further, in the template cleaning apparatus 40, the rods 451 are moved to position the support portions 452 above the upper side of the cleaning bath 42. Further, the inside of the cleaning bath 42 is filled with the cleaning liquid 43.

Thereafter, as shown in FIGS. 8B and 9B, the template 5 on the load port 20 is transferred into the template cleaning apparatus 40 by the carrier member 32 of the conveying apparatus 30. The carrier member 32 travels along the guide 33. Here, when the template 5 is transferred from the conveying apparatus 30 into the template cleaning apparatus 40, the gate valve 71 is opened. Then, the template 5 is placed on the support portions 452 attached to the rods 451 inside the template cleaning apparatus 40.

Then, as shown in FIGS. 8C and 9C, the gate valve 71 is closed. Further, inside the template cleaning apparatus 40, the rods 451 are moved down such that the template 5 is immersed into the cleaning liquid 43 in the cleaning bath 42.

Then, as shown in FIGS. 8D and 9D, the pressure increasing valve 48 is opened, and an inactive gas is supplied from the pressurizing pump 47 into the process chamber 41 until reaching the pressure set by the cleaning conditions. In this example, the inactive gas is supplied into the process chamber 41 until reaching 20 MPa. As the inactive gas, for example, nitrogen gas may be used. When and after the inactive gas is supplied, pressure control is performed by use of pressure regulators, such as the pressurizing pump 47, the pressure increasing valve 48, and the pressure reducing valve 49, and thereby a constant pressure is held in the process chamber 41. Further, together with this supply of the inactive gas, an electric power is supplied to the heater 46 such that the cleaning liquid 43 is heated to a temperature set by the cleaning conditions. In this example, the cleaning liquid 43 is heated to a temperature of 800° C. After the pressure and the temperature become stable, the pressure increasing valve 48 is closed.

Thereafter, as shown in FIGS. 8E and 9E, a cleaning process to the template 5 is started such that the high temperature-high pressure cleaning liquid 43 is agitated by use of the agitator 44 while the rods 451 are being rocked. The cleaning process is performed for a time period set by the cleaning conditions. In this example, the cleaning process is performed for 20 minutes. Here, since the rods 451 are being rocked, the cleaning liquid can infiltrate into interstices formed between the template 5 and the fixed resist, and thereby the fixed resist can be more easily removed from the template 5.

Then, as shown in FIGS. 8F and 9F, the rocking of the rods 451 and the agitation by the agitator 44 are stopped, and further the electric power supply to the heater 46 is stopped. Further, the pressure reducing valve 49 is opened, and thereby the inside of the process chamber 41 is opened to the atmosphere. As shown in FIGS. 8G and 9G, after the inside of the process chamber 41 reaches the atmospheric pressure, the rods 451 are moved to position the support portions 452 above the upper side of the cleaning bath 42.

Thereafter, as shown in FIG. 8H, the template 5 is transferred by the carrier member from the template cleaning apparatus 40 into the post-processing apparatus 60. When the template 5 is transferred out from the template cleaning apparatus 40, the gate valve 71 is opened, and, when the template 5 is transferred from the conveying apparatus 30 into the post-processing apparatus 60, the gate valve 72 is opened. Inside the post-processing apparatus 60, the template 5 is placed on the stage 62.

Then, as shown in FIG. 8I, the stage 62 of the post-processing apparatus 60 is rotated at a rotation number of 500 rpm. Further, together with this rotation, warm pure water is delivered from the nozzle 64, to prepare a post-process. The temperature of the warm pure water can be arbitrarily adjusted, and may be set to 60° C., for example.

Subsequently, as shown in FIG. 8J, the nozzle 64 is swung above the template 5 so that the warm pure water can be spread over the entire upper surface of the template 5. A rinse treatment is performed for a predetermined time period, such as 5 minutes. Thereafter, the swinging of the nozzle 64 is stopped, and the nozzle 64 is returned to a predetermined position. Here, the rotation number and the treatment time period may be arbitrarily set. Further, the nozzle 64 is swung in this example, but, depending on the post-process performance, the nozzle 64 may be fixed at a predetermined position above the template 5 and not swung, or a different swinging system may be used.

Then, as shown in FIG. 8K, the rotation number of the stage 62 is increased from 500 rpm to 2,000 rpm to spin off water. With this operation, drying of the template 5 is performed. The drying may be performed for a predetermined time period, such as 2 minutes. After the drying is finished, the rotation of the stage 62 is stopped. Here, the rotation number and the treatment time period may be arbitrarily set.

Then, the template 5 thus finished with the post-process is transferred by the carrier member 32 from the post-processing apparatus 60 to the load port 20. When the template 5 is transferred from the post-processing apparatus 60 to the conveying apparatus 30, the gate valve 72 is opened. As a result, the cleaning process to the template 5 is completed.

Here, in the explanation described above, the template cleaning apparatus 40 and the post-processing apparatus 60 are provided to perform the cleaning process and the post-process at different places, but the template cleaning apparatus 40 may be designed to perform both of the cleaning process and the rinse treatment. In this case, for example, the structure shown in FIG. 4 is altered such that the cleaning bath 42 of the template cleaning apparatus 40 can be rotated in a plane parallel with its bottom.

Further, in the explanation described above, the template cleaning apparatus 40 is exemplified by a case that the cleaning is performed to a single template 5. However, the support portions 452 may be attached to the rods 451 at a plurality of height levels so that a plurality of templates 5 can be supported. In this case, the cleaning conditions are determined to meet a template 5 having the largest remaining amount of fixed resist. Alternatively, templates having similar fixed resist ratios may be selected, based on defect maps obtained by an examination apparatus, so that a cleaning process can be performed to the templates in the same process chamber 41.

According to the first embodiment, the cleaning is performed by immersing the template 5 in the cleaning liquid 43 in a supercritical fluid state or subcritical fluid state. Consequently, there is provided an effect capable of removing the fixed resist deposited on the template 5, by cutting the Si—C bonds of the fixed resist without cutting the Si—O bonds of the template 5. As a result, it is possible to remove foreign matters on the template 5 and prolong the service life of the template 5.

Further, the state of the template 5 is measured before the cleaning, and the cleaning conditions are determined in consideration of the contamination degree of the template 5. Consequently, the cleaning process to a lightly contaminated template 5 can be finished earlier than that to a heavily contaminated template 5. As a result, it is possible to reduce the cleaning cost, as compared with case that the cleaning process is performed to every template 5 under constant conditions regardless of the state of the template 5.

### Second Embodiment

In the first embodiment, an explanation has been given of a template cleaning system and a template cleaning method, which are used for cleaning a template. In the second embodiment, an explanation will be given of an imprint method incorporating template cleaning.

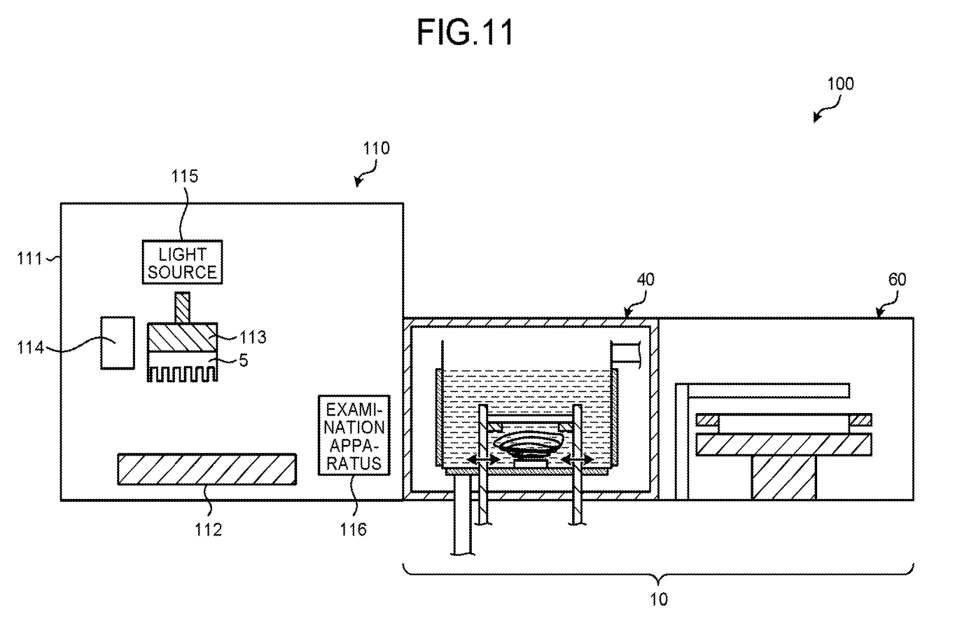

FIG. 11 is a view schematically showing a general structure of an imprint manufacturing system that includes a template cleaning function according to the second embodiment. The imprint manufacturing system 100 includes an imprint apparatus 110 and a template cleaning system 10. Since the template cleaning system 10 is the same as that described in the first embodiment, its description will be omitted.

The imprint apparatus 110 includes a wafer stage 112, a template holding mechanism 113, a resist supply portion 114, a light source 115, and an examination apparatus 116, disposed inside the chamber 111.

The wafer stage 112 is configured to hold a wafer treated as a processing object, by a mechanism, such as an electrostatic chuck mechanism or vacuum chuck mechanism. The wafer stage 112 can be moved in X- and Y-directions and a Z-direction by a drive mechanism (not shown).

The template holding mechanism 113 is configured to hold the template 5 having patterns to be formed on the wafer, by a mechanism, such as an electrostatic chuck mechanism or vacuum chuck mechanism. At this time, the template 5 is held such that the rugged side of the template 5 formed with patterns faces the wafer stage 112. Further, the template holding mechanism 113 is disposed above the wafer stage 112, and can be moved in the X- and Y-directions and the Z-direction by a drive mechanism (not shown).

The resist supply portion 114 is configured to drop a resist onto the wafer. For example, an ink jet system may be used to supply the resist onto the wafer. As the resist, for example, a solution containing a photo-curable resin may be used.

The light source 115 is configured to irradiate the resist with light in a state where the template 5 is pressed to the resist on the wafer, after the resist is dropped onto the wafer. Consequently, the resist containing the photo-curable resin is cured. In the case that the resist is made of a resin curable by ultraviolet rays, the light source 115 employed here is configured to output ultraviolet rays. This light source 115 has a function as a resin curing portion.

The examination apparatus 116 is configured to examine the state of a face of the template 5 after the imprint process. The examination apparatus 116 is formed of an optical microscope or scanning electron microscope, for example. The pattern formation face of the template 5 is imaged by the examination apparatus 116.

Here, FIG. 11 shows only the template cleaning apparatus 40 and the post-processing apparatus 60 adjacent to the imprint apparatus 110, but the template cleaning system 10 further includes the load port 20, the conveying apparatus 30, and the control apparatus 80, as shown in FIG. 5. In this case, the control apparatus 80 is configured to control not only the template cleaning system 10 but also the imprint apparatus 110.

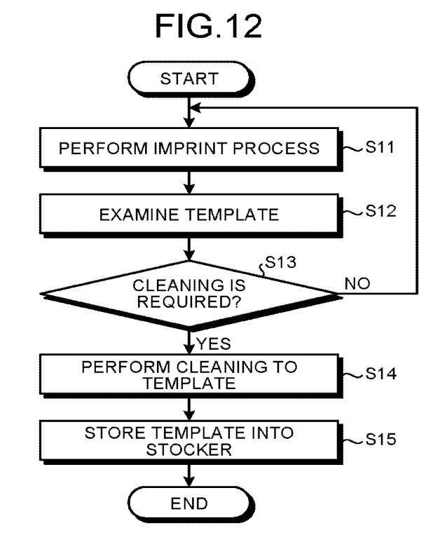

Next, an explanation will be given of an imprint method performed in the imprint system having the structure described above. FIG. 12 is a flow chart showing an example of the sequence of an imprint method according to the second embodiment. At first, an imprint process is performed in the imprint apparatus 110 (step S11). Since this imprint process is the same as that described with reference to FIGS. 1A to 1E, its detailed description will be omitted.

After the imprint process is finished, the template 5 used in the imprint process is examined by the examination apparatus 116 (step S12). More specifically, the pattern formation face of the template 5 is imaged. Then, based on the imaged data, the control apparatus 80 determines whether the template 5 requires cleaning (step S13). More specifically, the control apparatus 80 reads the imaged data, and determines whether the fixed resist and/or particles are deposited on the pattern formation face of the template 5.

If cleaning is unnecessary (No in the step S13), i.e., there is no deposition of the fixed resist or particles, the sequence returns to step S11. On the other hand, if cleaning is necessary (Yes in the step S13), i.e., there is deposition of the fixed resist and/or particles, cleaning is performed to the template in the template cleaning system 10 (step S14). This cleaning to the template 5 is the same as that described in the first embodiment. After the cleaning to the template 5 is finished, the template 5 is stored into a stocker by the carrier member 32 of the conveying apparatus 30 (step S15). As a result, the process is completed.

According to the second embodiment, after the imprint process is finished, the template 5 is examined, and, if the fixed resist and/or particles are deposited on the template 5, cleaning is performed to the template 5 in the template cleaning system 10. Consequently, it is possible to avoid using the template 5 in a subsequent imprint process without noticing deposition of the fixed resist on the template 5. As a result, it is possible to increase the manufacturing yield ratio of a device, such as a semiconductor device or liquid crystal display device, manufactured by use of an imprint process.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A template cleaning method comprising:
putting a template into a cleaning bath containing a cleaning liquid inside a first process chamber;
supplying an inactive gas into the first process chamber and heating the cleaning liquid so as to set temperature and pressure conditions that turn the cleaning liquid into a supercritical fluid state or subcritical fluid state; and
immersing the template in the cleaning liquid in the supercritical fluid state or subcritical fluid state for a predetermined time period.

2. The template cleaning method according to claim 1, wherein, in the immersing of the template, the cleaning liquid is agitated.

3. The template cleaning method according to claim 1, wherein the cleaning liquid is made of pure water.

4. The template cleaning method according to claim 1, wherein the supplying of the inactive gas and the heating of the cleaning liquid include
sealing the inactive gas in the first process chamber,
pressurizing the cleaning liquid, and
heating the cleaning liquid while controlling temperature by use of a heater attached to the cleaning bath.

5. The template cleaning method according to claim 4, wherein the first process chamber is pressurized inside to a pressure of 10 MPa or more and 100 MPa or less, and the cleaning liquid is heated to a temperature of 100° C. or more and 1,000° C. or less.

6. The template cleaning method according to claim 1, further comprising:
taking out the template from the cleaning liquid after the immersing the template;
rotating the template at a first rotational speed;
delivering a post-processing liquid onto the template;
stopping delivery of the post-processing liquid; and
rotating the template at a second rotational speed higher than the first rotational speed.

7. The template cleaning method according to claim 6, wherein, operations after the taking out the template from the cleaning liquid until the rotating of the template at a second rotational speed are performed in a second process chamber different from the first process chamber.

8. The template cleaning method according to claim 6, wherein the post-processing liquid is made of pure water or warm pure water.

9. The template cleaning method according to claim 1, further comprising:
examining a contamination degree on a pattern formation face of the template treated as a cleaning object, before the putting of the template into the cleaning bath; and
determining cleaning conditions for the template in consideration of the contamination degree;
wherein in the supplying of the inactive gas and in the heating of the cleaning liquid, the inactive gas is supplied into the first process chamber and the cleaning liquid is heated in accordance with the cleaning conditions thus determined.

10. The template cleaning method according to claim 9, wherein,
in the examining of the contamination degree, a fixed resist ratio is calculated based on pattern formation face information, the fixed resist ratio being a ratio of a fixed resist relative to the pattern formation face of the template, and the pattern formation face information indicating a state of the pattern formation face; and
in the determining of the cleaning conditions, the cleaning conditions to correspond to the fixed resist ratio thus calculated is obtained with reference to cleaning condition determination information, the cleaning condition determination information correlating cleaning conditions to fixed resist ratios.

11. The template cleaning method according to claim 10, wherein the cleaning condition determination information includes a temperature, a pressure, and a time period of a cleaning process.

12. The template cleaning method according to claim 11, wherein the cleaning condition determination information is set such that, with an increase in the fixed resist ratio, the temperature is higher, the pressure is higher, or the time period is longer.

13. The template cleaning method according to claim 1, wherein, in the immersing of the template, the template is rocked inside the cleaning liquid.

14. An imprint method comprising:
supplying a resist onto a wafer;
contacting a template to the resist, the template being placed to face the wafer and including patterns on a pattern formation face closer to the wafer;
curing the resist;
separating the template from the wafer;
examining the pattern formation face of the template;
putting the template into a cleaning bath containing a cleaning liquid inside a first process chamber, when a fixed resist is present on the pattern formation face of the template;
supplying an inactive gas into the first process chamber and heating the cleaning liquid so as to set temperature and pressure conditions that turn the cleaning liquid into a supercritical fluid state or subcritical fluid state; and
immersing the template in the cleaning liquid in the supercritical fluid state or subcritical fluid state for a predetermined time period.

15. A template cleaning apparatus comprising:
a process chamber configured to be airtightly closed;
a gas supply portion configured to supply an inactive gas into the process chamber;
a gas exhaust portion configured to exhaust gas from inside the process chamber;
a cleaning bath disposed inside the process chamber and supplied with a cleaning liquid cleaning a template;
a heater configured to heat the cleaning liquid; and
a controller configured to control a cleaning process to the template,
wherein the controller causes the gas supply portion to supply the inactive gas into the process chamber and causes the heater to heat the cleaning liquid, so as to set temperature and pressure conditions that turn the cleaning liquid into a supercritical fluid state or subcritical fluid state.

16. The template cleaning apparatus according to claim 15, further comprising an agitator configured to agitate the cleaning liquid inside the cleaning bath.

17. The template cleaning apparatus according to claim 15, wherein the cleaning liquid is made of pure water.

18. The template cleaning apparatus according to claim 15, wherein the controller controls the gas supply portion and the gas exhaust portion so as to pressurize an inside of the process chamber to a pressure of 10 MPa or more and 100 MPa or less, and controls the heater so as to heat the cleaning liquid to a temperature of 100° C. or more and 1,000° C. or less.

19. The template cleaning apparatus according to claim 15, wherein the controller
calculates a fixed resist ratio based on pattern formation face information, the fixed resist ratio being a ratio of a fixed resist relative to a pattern formation face of the template treated as a cleaning object, the pattern formation face information indicating a state of the pattern formation face;
obtains cleaning conditions to correspond to the fixed resist ratio thus calculated with reference to cleaning condition determination information, the cleaning condition determination information correlating cleaning conditions to fixed resist ratios; and
controls a cleaning process to the template in accordance with the cleaning conditions thus obtained.
